(19) United States
(12) Patent Application Publication
(10) Pub. No.: US 2017/0263422 A1
(43) Pub. Date: Sep. 14, 2017

(54) HEATED SUBSTRATE SUPPORT

(71) Applicant: Applied Materials, Inc., Santa Clara, CA (US)

(72) Inventors: Timothy Stuart OCHSNER, Santa Clara, CA (US); Robin L. TINER, Santa Cruz, CA (US); William Norman STERLING, Santa Clara, CA (US); Jonathan R. WILLEY, Cupertino, CA (US)

(21) Appl. No.: 15/288,577

(22) Filed: Oct. 7, 2016

Related U.S. Application Data
(60) Provisional application No. 62/305,900, filed on Mar. 9, 2016.

(51) Int. Cl. H01J 37/32; B23K 1/00; B23K 1/19; H05B 3/02; B23K 35/28; B23K 35/362; H05B 3/00; C25D 11/16; B23K 1/20

(52) U.S. Cl. CPC H01J 37/32724; C25D 11/16; B23K 1/0008; B23K 1/19; B23K 1/203; B23K 35/286; B23K 35/362; H05B 3/0014; H05B 3/026; C23C 16/50

(57) ABSTRACT

A substrate support and method of forming a substrate support are described herein. In one example, a substrate support includes an aluminum body having an upper surface configured to support a large area substrate, a heater element, and a filler material. The aluminum body has a groove formed therein. The heater element is disposed in the groove. The filler material is in contact with the heater element and fills the groove. The contact between the filler material and the perimeter of the heater element is the only material interface within the groove, and the filler material has a larger grain size than a grain size of the aluminum body.

### CROSS-REFERENCE TO RELATED APPLICATIONS

This application claims benefit of U.S. Provisional Patent Application Ser. No. 62/305,900, filed on Mar. 9, 2016, which herein is incorporated by reference.

### FIELD

Embodiments of the invention generally relate to a substrate support utilized in substrate processing and a method of fabricating the same.

### BACKGROUND

Heated substrate supports are often utilized in vacuum processing chambers to support substrates being processed for use in flat panel displays. Generally, substrate supports include one or more heater elements utilized to heat a metal body. Conventionally, the heater elements are disposed in a groove formed in the metal body, with a plug forged or welded to cover the heater elements to seal the groove formed in the support body. However, these designs often leave air pockets trapped between the heater elements and the substrate support. These air pockets prevent uniform heat transfer between the heater elements and the substrate support, and can create hot spots that burn out the heater, both of which can hinder processing.

Thus, a need exists for an improved heated substrate support and method of fabricating the same.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic side cross-sectional view of one embodiment of a processing chamber having a substrate support.

FIG. 2 is a partial cross-sectional view of one embodiment of the substrate support of FIG. 1.

FIG. 3 is a partial cross-sectional view of an alternative embodiment of the substrate support of FIG. 1.

### SUMMARY

A substrate support and method of forming a substrate support are described herein. In one example, a substrate support includes an aluminum body having an upper surface configured to support a large area substrate, a heater element, and a filler material. The aluminum body has a groove formed therein. The heater element is disposed in the groove. The filler material is in contact with the heater element and fills the groove. The contact between the filler material and the perimeter of the heater element is the only material interface within the groove, and the filler material has a larger grain size than a grain size of the aluminum body.

In another example, a method of forming a substrate support is provided that includes disposing a heater element into a groove formed in a surface of an aluminum body, and disposing a filler material into the groove such that the filler material is in contact with a perimeter of the heater element.

### DETAILED DESCRIPTION

Embodiments of the invention generally include a heated substrate support and methods of fabricating the same. The heated substrate support is illustratively described below as part of a plasma enhanced chemical vapor deposition (PECVD) system, such as a PECVD system available from AKT, a division of Applied Materials, Inc., located in Santa Clara, Calif. However, it should be understood that the heated substrate support has utility in other vacuum processing system configurations such as physical vapor deposition systems, ion implant systems, etch systems, other chemical vapor deposition systems and other systems in which use of a heated substrate support that provides good heating is desired.

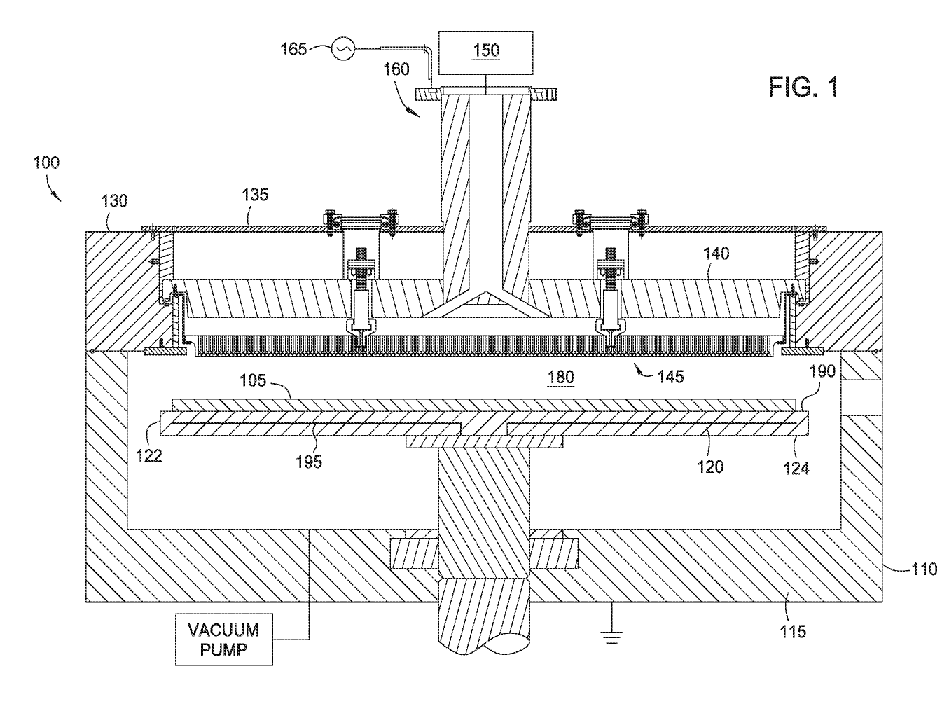

FIG. 1 is a schematic side cross-sectional view of one embodiment of a vacuum processing chamber 100. The chamber 100 is suitable for performing PECVD processes for fabricating circuitry on a large area substrate 105. The large area substrate 105 may be made of glass, a polymer, or other suitable substrate. The chamber 100 is configured to form structures and devices on the large area substrate 105 for use in the fabrication of liquid crystal displays (LCD's) or flat panel displays, photovoltaic devices for solar cell arrays, or other structures. The structures may include thin film transistors and p-n junctions utilized to form diodes for photovoltaic cells, among other structures.

The chamber 100 includes a chamber sidewall 110, a bottom 115, and a substrate support 120. The substrate support 120, such as a susceptor, supports the substrate 105 during processing. The chamber 100 also includes a lid structure 130, a backing plate 140, a cover plate 135, and a gas distribution showerhead 145. The gas distribution showerhead 145 is positioned opposite the substrate support 120 and the large area substrate 105.

The chamber 100 has a gas inlet 160 that is coupled to a gas source 150 and a plasma source 165. The plasma source 165 may be a direct current power source, a radio frequency (RF) power source, or a remote plasma source. The gas inlet 160 delivers process and/or cleaning gases from the gas source 150 to a processing region 180 defined in an area below the gas distribution showerhead 145 and above the substrate support 120. Gases present in the processing region 180 may be energized by the plasma source 165 to form a plasma. The plasma is utilized to deposit a layer of material on the substrate 105. Although the plasma source 165 is shown coupled to the gas inlet 160 in this embodiment, the plasma source 165 may be coupled to the gas distribution showerhead 145 or other portions of the chamber 100.

The substrate support 120 is centrally disposed within the chamber 100. Generally, the substrate support 120 has an upper surface 190 and a lower surface 124. The upper surface 190 is configured to support the substrate 105 during processing. The substrate support 120 includes a body 122 having at least one embedded heater element 195. The body 122, i.e., the upper and lower surfaces 190, 124, may be substantially rectangular in shape. The heater element 195, such as a resistive heater, disposed in the substrate support 120, is coupled to plasma source 165 and is utilized to controllably heat the substrate support 120 and large area substrate 105 positioned thereon to a predetermined temperature. The heater element 195 can be utilized to maintain the large area substrate 105 at a uniform temperature between about 150 and about 460 degrees Celsius.

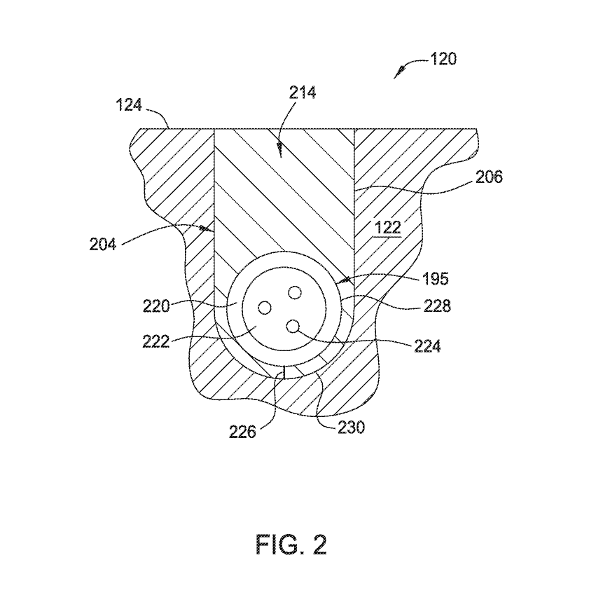

FIG. 2 depicts a partial cross-sectional view of the heater element 195 disposed in a groove 204 formed in the body 122 of the substrate support 120. In one embodiment, the heater element 195 is a conduit for flowing a heat transfer fluid or a resistive heater. For example, the heater element 195 may include a plurality of conductive elements 224 encased in a dielectric 222 and covered with a protective sheath 220. In one embodiment, the protective sheath 220 may be comprised of stainless steel.

The heater element 195 is disposed in a groove 204 formed in the lower surface 124 of the substrate support 120, as shown in the embodiment depicted in FIG. 2, or in the upper surface 190 of the substrate support 120. In implementations having a plurality of heater elements 195, each heater element 195 may be disposed in a separate groove 204 formed in the lower surface 124 or the upper surface 190 of the substrate support 120. The groove 204 formed in the body 122 of the substrate support 120 may have any suitable shape, number, size, or pattern as required to produce a desired heat distribution profile utilizing the heater element 195. The groove 204 may be deep enough such that the heater element 195 is positioned in a desired location upon insertion into the groove 204, and the depth may vary depending upon the application. In one embodiment, the depth of the groove 204 is calculated such that the heater element 195 is substantially centered in the body 122 of the substrate support 120.

In one embodiment, the walls 206 of the groove 204 may be substantially straight and parallel, while the bottom 230 of the groove 204 may be rounded. However, the groove 204 may be formed in any shape as desired. The walls 206 and bottom 230 of the groove 204 may be roughened or textured to increase their wetability and propensity for adhesion to form a tighter fit between the heater element 195 and the body 122 of the support 120. The textured surface further prevents movement between the heater element 195 and the body 122 of the substrate support 120.

The heater element 195 is encased in the body 122 using a process that enhances heat transfer between the body 122 and the heater element 195. In the embodiment depicted in FIG. 2, the heater element 195 is encased in the body 122 by dispensing a filler material 214 into the groove 204. The filler material 214 may be dispensed into the groove 204 by pouring, injecting or other suitable technique.

As shown in FIG. 2, a filler material 214 surrounds the heater element 195 and fills the groove 204. During fabrication, support elements, such as pins 226 are disposed at the bottom 230 of the groove 204 to support the heater element 195 within the groove 204 in a position that spaces the heater element 195 from the bottom 230 of the groove 204. The pins 226 may be may be fabricated from stainless steel, aluminum or other suitable material. The heater element 195 may be secured to the pins 226 with wire, so that the heater element 195 will not move when the filler material 214 is dispensed into the groove 204. For the purposes of this application, the interface(s) between the heater element 195 and the pins 226, or other support elements, is not considered part of a material interface with the heater element 195 as described below.

As discussed above, a filler material 214 is utilized to fill the groove 204 and encapsulate the heater element 195. The filler material 214 may be degassed in a crucible before it is dispensed into the groove 204, which removes porosity from the filler material 214. The degassing process may include one or more techniques to remove the gas from the filler material 214, including placing chlorine tablets in the material, infusing the material with a gas such as carbon dioxide or nitrogen, and applying a vacuum to the material. After the filler material 214 has been degassed, the filler material 214 is dispensed into the groove 204 until the groove 204 is filled. The heater element 195 and the body 122 of the substrate support 120 may be heated to a desired temperature while the filler material 214 is dispensed. For example, in one embodiment, the heater element 195 and the body 122 of the substrate support 120 may be heated in the range of approximately 200 to 500 degrees Celsius. Heating the heater element 195 and the body 122 of the substrate support 120 while dispensing the filler material 214 allows the filler material 214 to bond to the heater element 195 and the body 122 of the substrate support 120 while these elements are in a heated, expanded state. This can prevent future cracking or failure in the substrate support 120 when the heater element 195 and the body 122 of the substrate support 120 are heated and expand during use.

The filler material 214 encapsulates the heater element 195, bonding the heater element 195 to the body 122 of the substrate support 120. The filler material 214 substantially surrounds a perimeter 228 of the heater element 195, such that there is full thermal contact between the filler material 214 and the perimeter 228 of the heater element 195, except for any portion of the perimeter 228 that is covered by the pins 226 and/or the wiring, or is in direct contact with the body 122. As a result, the entire perimeter of the heater element 195 is in full thermal contact with the substrate support 120, through direct contact with the pins 226, through direct contact with the filler material 214, and/or through direct contact with the body 122. This full thermal contact between the heater element 195 and the substrate support 120 allows for excellent heat transfer between the heater element 195 and the substrate support 120. An atomic bond may be formed at the interface between the body 122 of the substrate support 120 and the filler material 214 (at the walls 206 and bottom 230 of the groove 204) creating full thermal contact between the body 122 and the filler material 214 at this interface. After formation, the body 122 of the substrate support 120 and heater element 195 are bonded together by the filler material 214, forming one cohesive support 120. The filler material 214 is dispensed into the groove 204 in a void-free manner, leaving substantially no voids remaining within the groove 204 after encapsulation. Thus, the material interface between the heater element 195 and the filler material 214 is the only material interface with the heater element 195 that is within the walls 206 and bottom 230 of the groove 204.

The filler material 214 may overfill the groove 204, such that filler material 214 extends externally beyond the lower surface 124 of the substrate support 120. The excess filler material 214 will allow for the groove 204 to remain filled, even after the filler material 214 shrinks upon cooling. After the filler material 214 is disposed in the groove 204, the lower surface 124 of the substrate support 120 is machined flat to leave the lower surface 124 in a smooth and planar condition. Prior to machining of the lower surface 124, the thickness of the body 122 and the depth of the filler material 214 that extends externally beyond the lower surface 124 may be configured such that after the lower surface 124 is machined to be smooth, the finished substrate support 120 has a desired thickness. Once the lower surface 124 of the substrate support 120 has been machined smooth, the substrate support 120 may be coated or anodized.

The filler material 214 may have a viscosity low enough to allow the filler material 214 to flow into the groove 204 in a manner that prevents void formation. In one example, the filler material 214 is aluminum. In another example, both the body 122 of the substrate support 120 and the filler material 214 comprise aluminum alloy 6061. In another example, the material of the body 122 of the substrate support 120 may be different from the filler material 214. For example, the material of the body 122 of the substrate support 120 may comprise aluminum alloy 6061, while the filler material 214 may be a casting alloy, such as aluminum alloy 356.

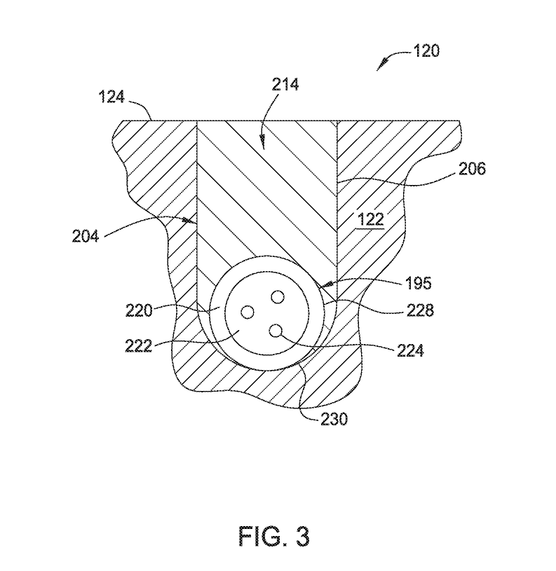

In one embodiment, rather than pouring the filler material 214 into the groove 204, a brazing technique may be used to fill the groove 204 with the filler material 214, such that the filler material 214 covers the heater element 195 and adheres to the body 122 of the substrate support 120. FIG. 3 shows an embodiment of a substrate support 120 formed using a brazing technique. As shown in FIG. 3, the heater element 195 is in direct contact with the bottom 230 of the groove 204. The filler material 214 may have a lower melting temperature than the melting temperature of the substrate support 120. For example, the filler material 214 may comprise aluminum alloy 4047, while the substrate support 120 may comprise aluminum alloy 6061. A solid piece of the filler material 214 may be placed in the groove 204. Because the filler material 214 has a lower melting temperature than the melting temperature of the substrate support 120, the solid piece of filler material 214 can be heated until it melts and fills the groove 204 to cover the exposed perimeter of the heater element 195, while at a temperature below the melting point of the substrate support 120 such that the substrate support 120 will remain solid as the heater element 195 is covered by the melted filler material 214. After the exposed perimeter of the heater element 195 is covered by the filler material 214, the entire perimeter of the heater element 195 is in full thermal contact with the substrate support 120. Thus, the material interface between the heater element 195 and the filler material 214 is the only material interface with the heater element 195 that is within the walls 206 and bottom 230 of the groove 204.

The brazing technique may include pouring liquid salt into the groove 204. The liquid salt transfers heat to the filler material 214, causing the filler material 214 to melt more efficiently. The liquid salt also fluxes oxide off of the substrate support 120 so that the molten filler material 214 will adhere to the walls 206 and the bottom 230 of the groove 204. Because the molten filler material 214 is denser than salt, the filler material 214 will push the salt out of the groove 204 as the liquid filler material 214 fills the groove 204, such that salt does not remain in the groove 204 after the brazing technique is complete.

After formation, the filler material 214 may visibly differ from the body 122 when viewing the support 120 from a cross section, as shown in FIG. 2, or when viewing the lower surface 124 of the support 120. For example, the filler material 214 may have a larger grain size than the grain size of the body 122. This could be the case where the body 122 of the substrate support 120 has been roll formed, because the body 122 will have a compressed grain size, smaller than the grain size of the filler material as cooled (neither cold nor hot worked). The filler material 214 having a larger grain size (neither cold nor hot worked) can be heated as needed to fill the groove 204 according to the methods described herein, without melting the body 122 having a smaller grain size. Additionally, the filler material 214 may differ in color or texture compared to that of the body 122 of the substrate support 120, due to a difference in how the filler material 214 and the body 122 material anodize. Because welding is not used to form the substrate support 120 shown in FIGS. 2 and 3, there are no weld effected regions within the groove 204 which may result in heat transfer discontinuities.

While the foregoing is directed to embodiments of the present invention, other and further embodiments of the invention may be devised without departing from the basic scope thereof, and the scope thereof is determined by the claims that follow.

1. A substrate support comprising:
an aluminum body having an upper surface configured to support a large area substrate, wherein the aluminum body has a groove formed therein;
a heater element disposed in the groove; and
a filler material in contact with a perimeter of the heater element that fills the groove, wherein the filler material is the only material disposed between the perimeter of the heater and the groove, wherein the filler material has a larger grain size than a grain size of the aluminum body.

2. The substrate support of claim 1, wherein there are no weld effected regions within the groove.

3. The substrate support of claim 1, wherein at least one of a color and a texture of the aluminum body is different from at least one of a color and a texture of the filler material.

4. The substrate support of claim 1, wherein the perimeter of the heater element is not in direct contact with the aluminum body and the filler material encapsulates the heater element.

5. The substrate support of claim 1, further comprising one or more support elements each in contact with the heater element and at least one of a bottom and a wall of the groove.

6. The substrate support of claim 1, wherein the heater element is centered along a thickness of the substrate support.

7. A substrate support comprising:
an aluminum body having an upper surface configured to support a substrate, wherein the aluminum body has a groove formed therein;
a heater element disposed in the groove; and
a filler material in contact with a perimeter of the heater element that fills the groove, wherein the filler material is the only material disposed between the perimeter of the heater and the groove, wherein the filler material has a larger grain size than a grain size of the aluminum body.

8. The substrate support of claim 7, wherein there are no weld effected regions within the groove.

9. The substrate support of claim 7, wherein the aluminum body has at least one of a color and a texture different from a color and a texture of the filler material.

10. The substrate support of claim 7, further comprising one or more support elements each in contact with the heater element and at least one of a bottom and a wall of the groove.

11. The substrate support of claim 7, wherein the heater element is centered along a thickness of the substrate support.

12. The substrate support of claim 7, wherein the perimeter of the heater element is not in direct contact with the aluminum body and the filler material encapsulates the heater element.

13. A method of forming a substrate support, comprising:
disposing a heater element into a groove formed in a surface of an aluminum body; and
disposing a filler material into the groove such that the filler material is in contact with a perimeter of the heater element, wherein the filler material is the only material disposed between the perimeter of the heater and the groove, wherein the filler material has a larger grain size than a grain size of the aluminum body.

14. The method of claim 13, wherein disposing the heater element into the groove comprises:
disposing one or more support elements in at least one of a bottom and a wall of the groove; and
disposing the heater element in the groove such that it rests on the one or more support elements.

15. The method of claim 13, wherein disposing the filler material into the groove comprises:
filling the groove with a molten material.

16. The method of claim 15 further comprising:
degassing the filler material prior to disposing the filler material into the groove.

17. The method of claim 13 further comprising:
machining exceed material filling the groove to create a planar surface on the aluminum body.

18. The method of claim 17 further comprising:
anodizing the planar surface on the aluminum body after machining the exceed material filling the groove.

19. The method of claim 13 further comprising at least one of:
heating the heater element and the aluminum body prior to disposing the filler material into the groove; and
texturizing at least one of a bottom and a wall of the groove prior to disposing the filler material into the groove.

20. The method of claim 13, wherein disposing the filler material into the groove comprises:
disposing the filler material in a solid state into the groove; and
exposing the filler material within the groove to enough salt to cause the filler material to melt.
